(19) United States
(12) Patent Application Publication
(10) Pub. No.: US 2020/0225764 A1
(43) Pub. Date: Jul. 16, 2020

(54) HUMAN INTERFACE DEVICE

(71) Applicant: LENOVO (SINGAPORE) PTE. LTD., Singapore (SG)

(72) Inventors: Daisaku Morita, YOKOHAMA (JP); Takumi Imai, YOKOHAMA (JP); Jonathan Jen-Wei Yu, Morrisville, NC (US)

(73) Assignee: LENOVO (SINGAPORE) PTE. LTD., SINGAPORE (SG)

(21) Appl. No.: 16/244,370

(22) Filed: Jan. 10, 2019

(51) Int. Cl. G06F 3/023; G06F 3/0488; H03K 17/96; H03K 17/967; G06F 3/0482

(52) U.S. Cl. CPC G06F 3/0236; G06F 3/04883; G06F 3/0482; H03K 17/967; H03K 17/96

(57) ABSTRACT

A human interface device (HID) is configured to communicate with a control system that can communicate with user mechanisms. The HID includes comprises an outer input component; an inner input component radially inward of the outer input component; and a central input component radially inward of the inner input component. The central input component is configured to display a menu list of user mechanism icons which correspond to respective user mechanisms. The inner input component is configured to select one of the user mechanism icons and thereby one of the respective user mechanisms. The outer input component is configured to control the respective user mechanism if the respective user mechanism employs audio.

### BACKGROUND OF THE INVENTION

The present invention generally relates to human interface devices and, more particularly, to apparatus and methods of enabling the control of electronic devices and/or applications.

An electronic control system may serve as a hub that communicates with and controls different electronic devices and/or applications. A user can control, via the hub, the different electronic devices and/or applications. However, the ease of controlling the electronic devices and/or applications is limited by the ease of using the hub.

As can be seen, there is a need for improved apparatus and methods of human interaction to control different electronic devices and/or applications.

### SUMMARY OF THE INVENTION

In one aspect of the present invention, a human interface device (HID) configured to communicate with a control system that can communicate with user mechanisms, the HID comprises an outer component; an inner input component radially inward of the outer component; and a central input component radially inward of the inner input component; wherein the central input component is configured to display a menu list of user mechanism icons which correspond to respective user mechanisms; wherein the inner input component is configured to select one of the user mechanism icons and thereby one of the respective user mechanisms; wherein the outer component is configured to control the respective user mechanism if the respective user mechanism employs audio.

In another aspect of the present invention, a human interface device (HID) configured to communicate with a control system that can communicate with user mechanisms, the HID comprises an outer component; an inner input component radially inward of the outer component; a central input component radially inward of the inner input component; and a controller configured to: receive outer user depression signals generated from user depressions of the outer component; receive inner user touch signals generated from user touches of the inner input component; and receive central user depression signals generated from user depressions of the central component.

In a further aspect of the present invention, apparatus for controlling user mechanisms comprises a human interface device (HID) having: an outer input component configured to be depressed by a user; an inner input component radially inward of the outer component and configured to be touched but not depressed by the user; a central component radially inward of the inner input component and configured to be depressed by the user; and a microcontroller in communication with the outer component, the inner input component, and the central component; and a control system in communication with the HID, wherein the control system is configured to communicate with a plurality of user mechanisms.

These and other features, aspects and advantages of the present invention will become better understood with reference to the following drawings, description and claims.

### BRIEF DESCRIPTION OF THE DRAWINGS

FIG. 1A is a plan view of a human interface device (HID) which can be configured to communicate with a control system or hub that communicates with user mechanisms, according to an embodiment of the present invention.

FIG. 1B is a schematic diagram of the HID and control system in FIG. 1A, according to an embodiment of the present invention.

FIG. 2A is a flow diagram of operational phases of the HID of FIG. 1A, according to an embodiment of the present invention.

FIG. 2B is a flow diagram of some operational phases of the HID in FIG. 2A, according to an embodiment of the present invention.

FIG. 3 is a plan view of user action/touches of the HID of FIG. 1A, according to an embodiment of the present invention.

FIGS. 4A-C are plan view of LED states of operation of the HID of FIG. 1A, according to an embodiment of the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features. However, any single inventive feature may not address any of the problems discussed above or may only address one of the problems discussed above. Further, one or more of the problems discussed above may not be fully addressed by any of the features described below.

As will be appreciated by one skilled in the art, aspects of the present invention may be embodied as a system, method, or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable media having computer readable program code embodied thereon.

Any combination of one or more computer readable storage media may be utilized. A computer readable storage medium is an electronic, magnetic, optical, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium is any tangible medium that can store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable storage medium that can direct a computer, other programmable data processing apparatus, or other devices to function in a particular manner, such that the instructions stored in the computer readable storage medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Broadly, the present invention provides apparatus and methods for controlling user mechanisms with a human interface device (HID). The user mechanisms can include electronic devices such as a computer and display screen. They can also include software applications such as Zoom™ and Skype™. The HID can communicate with a control system or hub which, in turn, can communicate with the user mechanisms.

According to the present invention, the HID may activate a display of a menu list of user mechanisms. The HID may then navigate to and select a user mechanism. Next, the HID may control the volume of an audio/video call.

Also, according to the present invention, the HID may be configured to determine whether a user touch of the HID was intentional or accidental. For example, the HID may determine whether a length of time of a user touch exceeds a threshold. If so, the HID can consider the user touch as intentional.

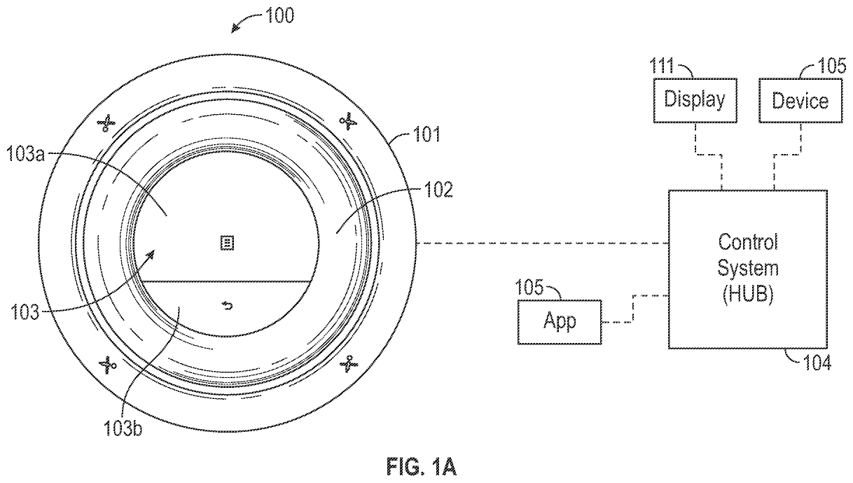

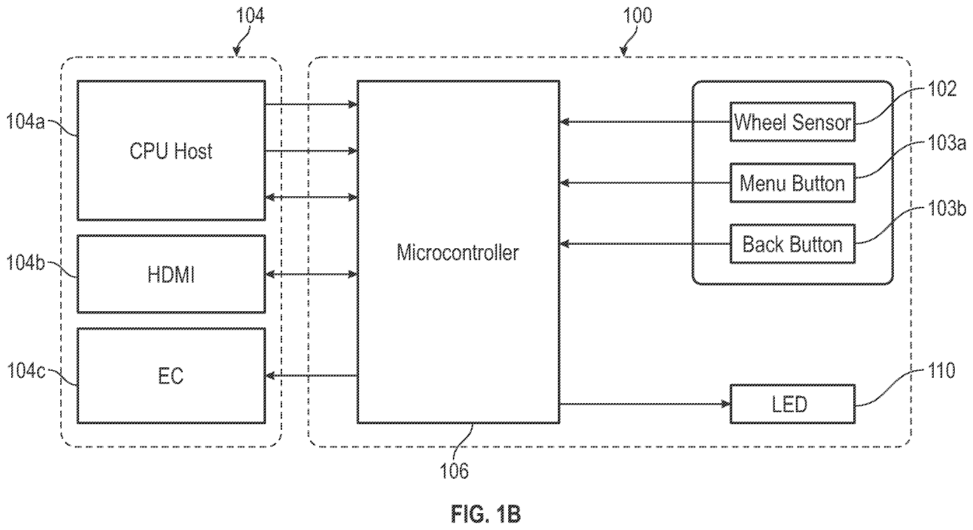

FIG. 1A depicts a human interface device (HID) 100 according to an embodiment of the present invention. The HID 100 may have a circular configuration in a top, plan view. In embodiments, the HID 100 may include an outer component 101, an inner input component 102 radially inward of the outer component, and a central component 103 radially inward of the inner input component. In certain embodiments, the central component 103 may include a first central portion 103a and a second central portion 103b.

The HID 100 can be configured to communicate with a control system 104 which, in turn, can be configured to communicate with one or more user mechanisms 105. The user mechanisms 105 may include electronic devices such as a computer and a computer display 111. The user mechanisms 105 may also include software applications and, more specifically, access points to software applications. Some applications may include Zoom™ and Skype™.

In FIG. 1B, the control system 104 that communicates with the HID 100 may include, in embodiments, a central processing unit (CPU) 104a, an HDMI port(s) 104b, and an embedded controller 104c, all of which may be in communication with a microcontroller 106 of the HID 100, as described below.

Still referring to FIG. 1B, in embodiments, the HID 100 may include the inner input component (e.g., wheel sensor) 102, the first central portion (e.g., menu button) 103a, and the second central portion (e.g., back button) 103b. The HID 100 may further include an LED(s) 110. The foregoing parts of the HID 100 may be controlled by the microcontroller 106 in the HID 100.

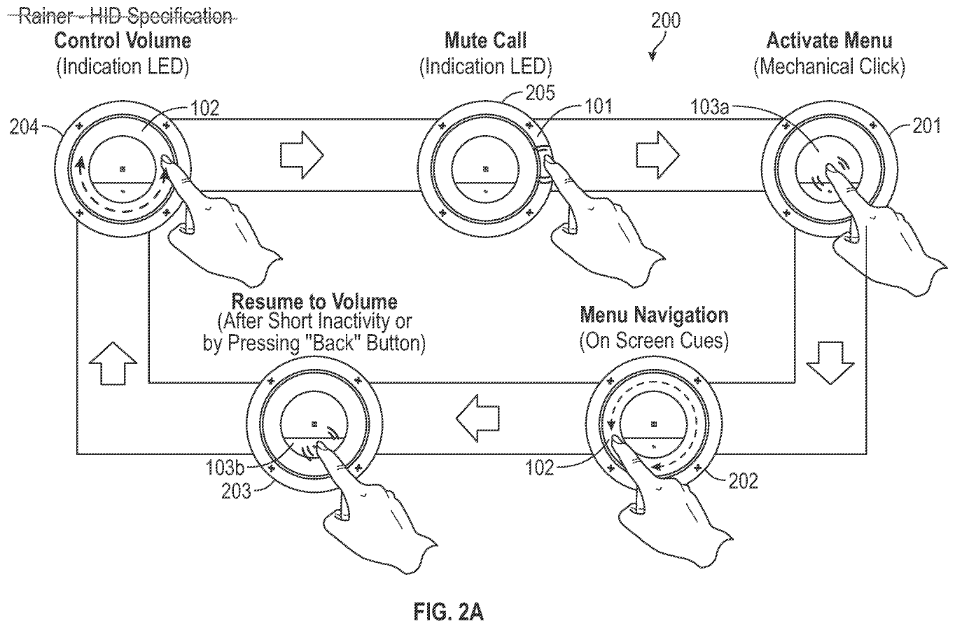

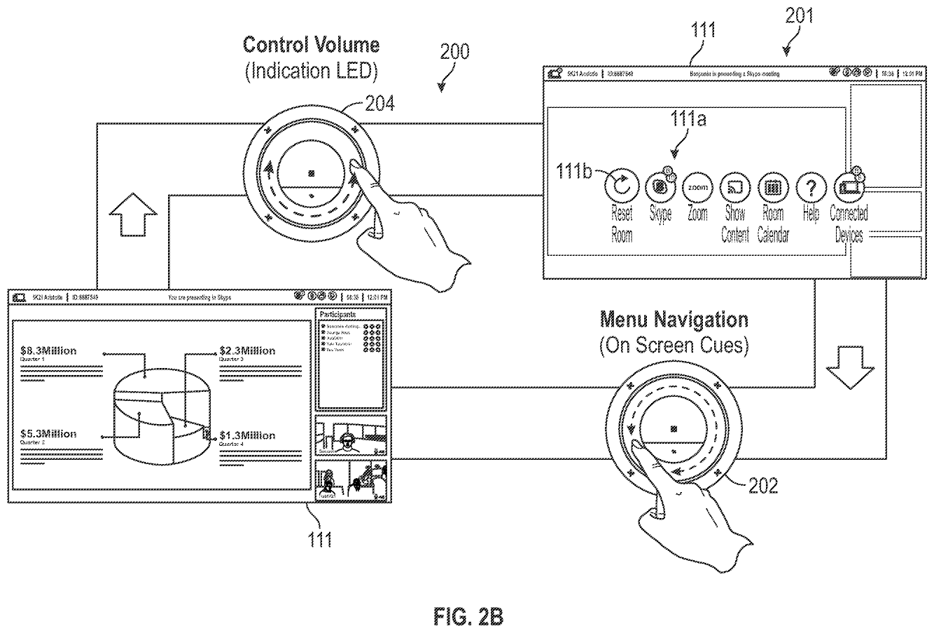

Referring to FIGS. 1A-1B, the central component 103 can be configured to display, via the microcontroller 106 and the control system 104, a menu list 111a of user mechanism icons 111b (FIG. 2B). The inner input component 102 can be configured to select and activate, via the microcontroller 106 and the control system 104, one of the user mechanism icons 111a. The activated user mechanism icon 111a can, in turn, activate the respective user mechanism 105. The outer component 101 can be configured to control the selected user mechanism if the selected user mechanism employs audio, such as Skype™.

Accordingly, as shown in FIG. 2A, a method 200 includes using the HID 100 in different operating states. Moreover, different user interactions with the HID 100 can place the HID 100 in different operating states. The operating states can occur in various sequences. Or, the HID 100 can operate in only a single operating state, according to the present invention.

In embodiments, a menu activation state 201 may be initiated by a user depressing the first central input portion 103a. In the menu activation state 201, the menu list 111a of user mechanism icons 111b may be shown on the computer display 111 (FIG. 2B).

A menu navigation state 202 may be initiated by a user touching (but not depressing) the inner input component 102. The user touching can enable the user to navigate to and select one of the user mechanism icons 111b shown on the display 111 (FIG. 2B) In embodiments, the touching can be a continuous touching with movement, such as at different points of the inner input component 102. For example, the continuous touching with movement may be a circular touching by the user's finger around the inner input component 102. In certain embodiments, the continuous touching with movement may be for a period of time that is at least equal to a navigation time threshold, as determined by the microcontroller 106. In still other embodiments, the continuous touching with movement may be an angular distance that is at least a navigation angular distance threshold, as determined by the microcontroller 106.

Still referring to FIG. 2A, a volume activation state 203 may be initiated by a user depressing the second central portion 103b. In the volume activation state 203, a volume control for audio of a user mechanism 105, such as Skype™, may be turned on.

A volume control state 204 may be initiated by a user touching (but not depressing) the inner input component 102. The user touching can enable the user to increase or decrease an audio volume of a user mechanism 105, such as Skype™. In embodiments, the touching can be a continuous touching with movement, such as at different points of the inner input component 102. For example, the continuous touching with movement may be a circular touching by the user's finger around the inner input component 102. In certain embodiments, the continuous touching with movement may be for a period of time that is at least a volume time threshold, as determined by the microcontroller 106. In still other embodiments, the continuous touching with movement may be an amount of angular distance that exceeds a volume angular distance threshold, as determined by the microcontroller 106.

Also in FIG. 2A, an audio state 205 may be initiated by a user depressing the outer component 101. In the audio state 205, a user depressing may mute the audio of a user mechanism 105, such as Skype™. Another user depressing may un-mute the audio.

FIG. 2B depicts an exemplary menu list 111a of user mechanism icons 111b in a display 111 during a menu activation state 201. In the menu navigation state 202, the user selects a user mechanism icon 111b to activate a user mechanism 105. The activated user mechanism 105, such as Skype™, can then be shown in the display 111. Once activated, and for an audio user mechanism, the volume control state 204 can be used to control the audio volume.

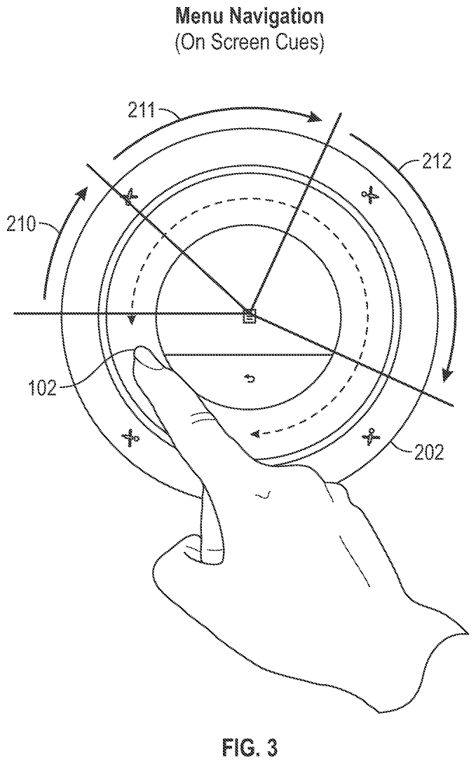

FIG. 3 depicts continuous touching with movement during the menu activation state 202, according to an exemplary embodiment. First, a user's finger may continuously touch the inner input component 102 and move over a first angular distance 210 (i.e., first angular distance threshold). Then, the user's finger may continue the continuous touching and move over a second angular distance 211 (i.e., second angular distance threshold which includes the first angular distance threshold). Next, the user's finger may continue the continuous touching and move over a third angular distance 212 (i.e., third angular distance threshold which includes the first and second angular distance thresholds).

In embodiments, the third angular distance may be greater than the second angular distance, and the second angular distance may be greater than the first angular distance. For example, the first angular distance may be 36°, the second angular distance may be 60°, and the third angular distance may be 90°.

In embodiments, the present invention, and in particular the microcontroller 106, can execute a predetermined processing if the user continuously touches the inner input component 102 over a first angular distance threshold 210. The present invention may re-execute the predetermined processing if the user continuously touches the inner input component 102 over a second angular distance threshold 211 after moving over the first angular distance threshold, with the second angular distance threshold being greater than the first angular distance threshold.

Thus, in certain embodiments, the microcontroller 106 can be configured to receive inner user touch signals generated from user touches, in a direction of a touching path, of the inner input component (FIG. 3). The microcontroller 106 can then (1) determine an initial angular distance of the user touches of the inner input component and (2) determine whether the initial angular distance is equal to at least a first angular distance threshold 210 and a second angular distance threshold 211. According to embodiments, the first and second angular distance thresholds 210, 211 are sequential distances along and in the direction of the touching path. The first angular distance threshold 210 is positioned before the second angular distance threshold 211 along the touching path. According to embodiments, the second angular distance threshold 211 is greater than the first angular distance threshold 210.

The microcontroller 106 may then execute a predetermined processing if the user continuously touches the inner input component 102 over the entire first angular distance threshold 210. And the microcontroller 106 may re-execute the predetermined processing if the user continuously touches the inner input component 102 over the entire second angular distance threshold 211 after continuously touching over the entire first angular distance threshold.

In FIG. 3, according to still further embodiments, the present invention may provide a plurality of additional angular distance thresholds 212 along and in the direction of the touching path, which are in addition to the first and second angular distance thresholds 210, 211. The additional angular distance thresholds 212 are sequential distances along and in the direction of the touching path. The additional angular distance thresholds are positioned after the second angular distance threshold along the touching path. In embodiments, each additional angular distance threshold is equal to each other. In other embodiments, each additional angular distance threshold is at least equal to the second angular distance threshold.

With the foregoing, the microcontroller 106 can be further configured to determine a subsequent angular distance of the user touches of the inner input component, wherein the subsequent angular distance is after the initial angular distance along the touching path. The microcontroller can be further configured to re-execute the predetermined processing, when the subsequent angular distance is equal to at least one of the second 211 and additional angular distance thresholds 212.

For example, by the user's continuous touching over the first angular distance, and then stopping, the user may select the first user mechanism icon 111b in the menu list 111a. By the user continuously touching over the first and second angular distances, and then stopping, the user may select the second user mechanism icon 111b in the menu list 111a. By the user continuously touching over the first, second, and third angular distances, and then stopping, the user may select the third user mechanism icon 111b in the menu list 111a. User selection of additional user mechanism icons may be enabled by additional angular touching movement equal to the third angular distance, as an example.

In embodiments, the inner input component 102 may, upon the user touching the component 102, send user inner component touch signals to the microcontroller 106 in the HID 100. In turn, the microcontroller 106 may be configured to receive the user inner component touch signals and determine an angular distance of the user touches of the inner input component. If the determined angular distance is at least equal to an angular distance threshold—for example, the first angular distance threshold—the first user mechanism icon is selected.

In other embodiments, the microcontroller 106 may be configured to determine if a user's touch of the inner input component 102 is at least a minimum touch threshold. In embodiments, the minimum touch threshold is based on angular distance of the user's touch. If a user's touch is not at least equal to the minimum touch threshold, the microcontroller 106 may determine that the touch was accidental and therefore the touch is ignored by the HID 100. If the user's touch is at least equal to the minimum touch threshold, the microcontroller 106 may determine that the touch was intentional and therefore the touch is to be considered as whether meeting an angular distance threshold. For example, the minimum touch threshold may be 6°. In such example, if a user's continuous touch with movement of the inner input component is at least 6°, the touch will be determined as intentional and continuous. The microcontroller 106 will also use such intentional touch to determine if the angular distance threshold is met.

In yet other embodiments, the microcontroller 106 may be configured to determine if a time of non-touching between consecutive user touches of the inner input component 102 is less than a time threshold. If the determined time is less than the time threshold, the microcontroller is further configured to consider and determine that the touches before and after the determined time are part of a continuous touch. If the determined time is equal to or greater than the time threshold, the touches before and after the determined time are not considered as part of a continuous touch. For example, the time threshold may be 100 ms.

In further embodiments, the microcontroller 106 may be configured to receive outer user depression signals generated from user depressions of the outer component 101. The microcontroller 106 may also be configured to receive central user depression signals generated from user depressions of the central component 103. The microcontroller 106 may use the foregoing depression signals to initiate activation of HID 100 operating states described above.

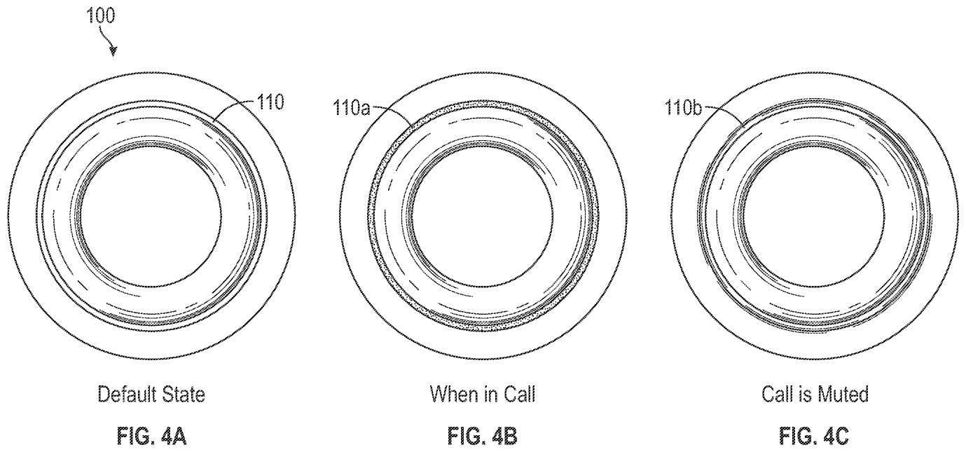

FIGS. 4A-4C show exemplary embodiments of operating states of the HID 100 when an audio/video broadcast is possible when a user mechanism 105 employs audio/video, such as Skype™. In FIG. 4A, the HID 100 includes an LED 110. In this default state, the LED is not “on” and there is no audio/video broadcast. In FIG. 4B, the LED is in a first LED state 110a and shows a first color to indicate that an audio component of the user mechanism is “on”. In FIG. 4C, the LED is in a second LED state 110b and shows a second color to indicate that an audio component of the user mechanism is “muted”.

It should be understood, of course, that the foregoing relates to exemplary embodiments of the invention and that modifications may be made without departing from the spirit and scope of the invention as set forth in the following claims.

We claim:

1. A human interface device (HID) configured to communicate with a control system that can communicate with user mechanisms, the HID comprising:
an outer component;
an inner input component radially inward of the outer component; and
a central component radially inward of the inner input component;
wherein the central component is configured to display a menu list of user mechanism icons which correspond to respective user mechanisms;
wherein the inner input component is configured to select one of the user mechanism icons and thereby one of the respective user mechanisms;
wherein the outer component is configured to control the respective user mechanism if the respective user mechanism employs audio.

2. The HID of claim 1, wherein the outer component is configured to be depressed by a user.

3. The HID of claim 1, wherein the inner input component is configured to be touched but not depressed by a user.

4. The HID of claim 1, wherein the central component is configured to be depressed by a user.

5. The HID of claim 1, further comprising:
a controller configured to:
receive user touch signals generated from user touches of the inner input component; and
determine an angular distance of the user touches of the inner input component.

6. The HID of claim 1, further comprising:
a controller configured to:
receive user touch signals generated from user touches of the inner input component; and
determine a time between user touches of the inner input component.

7. The HID of claim 1, further comprising an LED adjacent the outer component and the inner input component and configured to identify the status of user interaction of a respective user mechanism that employs audio.

8. A human interface device (HID) configured to communicate with a control system that can communicate with user mechanisms, the HID comprising:
an outer component;
an inner input component radially inward of the outer input component;
a central component radially inward of the inner input component; and
a controller configured to:
receive inner user touch signals generated from user touches, in a direction of a touching path, of the inner input component;
determine an initial angular distance of the user touches of the inner input component;
determine whether the initial angular distance is equal to at least a first angular distance threshold and a second angular distance threshold;
wherein the first and second angular distance thresholds are sequential distances along and in the direction of the touching path;
wherein the first angular distance threshold is positioned before the second angular distance threshold along the touching path;
wherein the second angular distance threshold is greater than the first angular distance threshold;
execute a predetermined processing if the user continuously touches the inner input component over the entire first angular distance threshold;
re-execute the predetermined processing if the user continuously touches the inner input component over the entire second angular distance threshold after continuously touching over the entire first angular distance threshold.

9. The HID of claim 8, wherein the inner input component is configured to be touched but not depressed by a user.

10. The HID of claim 8, further comprising:
a plurality of additional angular distance thresholds along and in the direction of the touching path;
wherein the additional angular distance thresholds are sequential distances along and in the direction of the touching path;
wherein the additional angular distance thresholds are positioned after the second angular distance threshold along the touching path;
wherein each additional angular distance threshold is equal to each other;
wherein each additional angular distance threshold is at least equal to the second angular distance threshold;
wherein the controller is further configured to determine a subsequent angular distance of the user touches of the inner input component;
wherein the subsequent angular distance is after the initial angular distance along the touching path;
wherein the controller is further configured to re-execute the predetermined processing, when the subsequent angular distance is equal to at least one of the second and additional angular distance thresholds.

11. The HID of claim 8, wherein the controller is further configured to:
determine an amount of time between consecutive user touches of the inner input component; and
determine whether the amount of time exceeds a time threshold.

12. The HID of claim 8, wherein the controller is further configured to:
alter an LED that identifies an operating status of one of the user mechanisms.

13. The HID of claim 8, wherein the controller is further configured to:
communicate with the control system that can operate a display of a menu list of the user mechanisms.

14. The HID of claim 8, wherein the controller is further configured to:
determine whether the angular distance is at least equal to a minimum touch threshold;
wherein, when the angular distance is at least equal to the minimum touch threshold, the controller determines that the touch was intentional.

15. Apparatus for controlling user mechanisms, comprising:
a human interface device (HID) having:
an outer component configured to be depressed by a user;
an inner input component radially inward of the outer component and configured to be touched but not depressed by the user;
a central component radially inward of the inner input component and configured to be depressed by the user; and
a microcontroller in communication with at least the inner input component;
wherein the microcontroller is configured to:
determine an amount of time between consecutive user touches of the inner input component; and
determine whether the amount of time is less than a time threshold;
wherein, when the amount of time is less than the time threshold, the controller determines the consecutive touches to be part of a continuous touch; and
a control system in communication with the HID, wherein the control system is configured to communicate with a plurality of user mechanisms.

16. The apparatus of claim 14, wherein the microcontroller is configured to:
determine an angular distance of user touches of the inner input component; and
determine whether the angular distance is at least equal to at least one of an angular distance threshold and a minimum touch threshold.

17. The apparatus of claim 14, wherein, when the amount of time is at least equal to the time threshold, the controller determines the consecutive touches to not be part of a continuous touch.

18. The apparatus of claim 14, wherein the plurality of user mechanism include an electronic device.

19. The apparatus of claim 14, wherein the plurality of user mechanism include a software application.
